(19) United States
(12) Patent Application Publication
(10) Pub. No.: US 2025/0149078 A1
(43) Pub. Date: May 8, 2025

(54) DRAM with Analog Refresh Loop

(71) Applicant: MIXED SIGNAL MACHINES LTD., Hoshaya (IL)

(72) Inventors: Bnaya Ben Nun, Hoshaya (IL); Amir Shimon, Tel Aviv (IL)

(21) Appl. No.: 18/915,412

(22) Filed: Oct. 15, 2024

Related U.S. Application Data
(60) Provisional application No. 63/547,690, filed on Nov. 8, 2023.

(51) Int. Cl. G11C 11/406; G11C 11/408; G11C 11/4096

(52) U.S. Cl. CPC G11C 11/406; G11C 11/4096; G11C 11/4087

(57) ABSTRACT

A Dynamic Random-Access Memory (DRAM) device includes a plurality of DRAM cells, a control circuit and an analog Arithmetic-Logic Unit (aALU). The DRAM cells include respective storage capacitors configured to be charged to respective voltages. The control circuit is configured to read a voltage from a target DRAM cell and to refresh the target DRAM cell using a refresh voltage that is derived from the read voltage. The aALU is configured to derive the refresh voltage from the read voltage such that the refresh voltage approximates a voltage previously written to the target DRAM cell, by performing analog operations.

### CROSS-REFERENCE TO RELATED APPLICATIONS

This application claims the benefit of U.S. Provisional Patent Application 63/547,690, filed Nov. 8, 2023, whose disclosure is incorporated herein by reference.

### FIELD OF THE INVENTION

The present invention relates generally to Dynamic Random-Access Memories (DRAMs), and particularly to refresh operations in DRAMs.

### BACKGROUND OF THE INVENTION

Dynamic Random-Access Memory (DRAM) is a highly efficient storage technique, using small-area capacitors for storage elements. Multilevel DRAM further increases the storage efficiency by storing multiple bits per capacitor, without significantly increasing the cell size.

Background on multilevel DRAM can be found, for example, in “Design and Characterization of a Multilevel DRAM”, Koob et. al. (IEEE Transactions on Very Large-Scale Integration (VLSI) Systems, VOL. 19, NO. 9, September 2011), in which the authors describe a Multilevel DRAM (MLDRAM) that uses reference and data cell signals generated in the cell array using charge sharing. A single-step sensing method uses multiple reference signals in parallel. The authors proceed to describe an operational 19200-cell MLDRAM test chip in 1.8-V, 180-nm mixed-signal CMOS that allows 1, 1.5, 2, 2.25, and 2.5 bits-per-cell operation using 2, 3, 4, 5, and 6 data signal levels, respectively.

In “A Multi-Level DRAM with Fast Read and Low Power Consumption”, Liu et. al. (2005 IEEE Workshop on Microelectronics and Electron Devices, 2005—WMED '05), the authors present a multi-level DRAM design, which can store 3 voltage levels (0, Vcc, and Vcc/2) in a single memory cell and requires no special reference voltages, simplifying the design of the peripheral circuits.

Lastly, U.S. Pat. No. 5,612,912 discloses a multi-level DRAM, in which one of multiple voltage levels may be stored in each memory cell. In a four-level system, each of a pair of bit-lines is divided into two sub-bit-lines which are connected to respective sense amplifiers. Dummy cells matching the storage cell are provided on each sub-bit-line to balance the capacitances. The stored voltage is dumped onto left and right sub-bit-lines which are then isolated, and one of the voltages is then sensed to provide a sign bit. A second reference level is generated by dumping the charge associated with the sign bit over three sub-bit-lines and the magnitude bit is sensed using that reference. The stored voltage is restored by charge sharing a sign bit charge on two bit-lines with a magnitude bit charge on one bit-line.

### SUMMARY OF THE INVENTION

An embodiment of the present invention that is described herein provides a Dynamic Random-Access Memory (DRAM) device including a plurality of DRAM cells, a control circuit and an analog Arithmetic-Logic Unit (aALU). The DRAM cells include respective storage capacitors configured to be charged to respective voltages. The control circuit is configured to read a voltage from a target DRAM cell and to refresh the target DRAM cell using a refresh voltage that is derived from the read voltage. The aALU is configured to derive the refresh voltage from the read voltage such that the refresh voltage approximates a voltage previously written to the target DRAM cell, by performing analog operations.

In some embodiments, one or more of the DRAM cells serve as one or more reference DRAM cells that are programmed with one or more respective reference voltages, and the aALU is configured to derive the refresh voltage for the target DRAM cell based on (i) the voltage read from the target DRAM cell, (ii) one or more voltages read from the one or more reference DRAM cells, and (iii) a time that elapsed since the voltage was previously written to the target DRAM cell.

In a disclosed embodiment, the aALU includes (i) one or more reference sampling capacitors configured to store one or more sampled reference DRAM cell voltages and (ii) a data sampling capacitor configured to store a sampled target DRAM data voltage.

In an example embodiment, the aALU includes a voltage-ratio amplifier that is configured to produce the refresh voltage by multiplying a reference voltage among the one or more reference voltages by a ratio between the corrected target DRAM cell voltage and a respective corrected reference DRAM cell voltage among the one or more corrected reference DRAM cell voltages, thereby mitigating a decay of the target DRAM cell.

In some embodiments, the aALU includes a differential amplifier configured to (i) amplify a difference between the precharge voltage and the data-read voltage by a reciprocal of a charge sharing attenuation factor, thereby producing a corrected target DRAM cell voltage for the target DRAM cell, and (ii) amplify one or more differences between the precharge voltage and the one or more reference-read voltages by a reciprocal of a charge sharing attenuation factor, thereby producing one or more corrected reference DRAM cell voltages for the one or more reference DRAM cells.

In an embodiment the aALU is configured to produce the refresh voltage by adding a product of (i) a DRAM cell decay measure and (ii) a difference between a corrected first reference voltage among the one or more corrected reference voltages and a respective first reference voltage among the one or more reference voltages, to a first reference voltage among the one or more reference voltages, thereby compensating for additive noise that is induced on the storage capacitors.

In an example embodiment, the aALU is configured to calculate the DRAM cell decay measure by dividing a difference between a first reference voltage and a second reference voltage by a difference between a first corrected reference voltage and a second corrected reference voltage.

In some embodiments, the aALU includes a differential amplifier, which is configured to amplify a difference between a precharge voltage and a voltage read from the target DRAM cell, and the aALU is configured to produce a corrected target DRAM cell voltage for the target DRAM cell based on an analog output of the differential amplifier.

In an embodiment, in deriving the refresh voltage from the read voltage, the aALU is configured to compensate for one or more of (i) a process variation affecting the DRAM device, (ii) a variation associated with a supply voltage of the DRAM device, and (iii) a variation associated with a temperature of the DRAM device.

There is additionally provided, in accordance with an embodiment of the present invention, an analog Dynamic Random-Access Memory (analog-DRAM) device, inclusing a plurality of storage capacitors that are configured to store a continuous range of an electric charge, representing a continuously defined analog value.

There is also provided, in accordance with an embodiment of the present invention, a method including operating a plurality of Dynamic Random-Access Memory (DRAM) cells including respective storage capacitors configured to be charged to respective voltages. Using a control circuit, a voltage is read from a target DRAM cell and the target DRAM cell is refreshed using a refresh voltage that is derived from the read voltage. Using an analog Arithmetic-Logic Unit (aALU), the refresh voltage is derived from the read voltage such that the refresh voltage approximates a voltage previously written to the target DRAM cell, by performing analog operations.

The present invention will be more fully understood from the following detailed description of the embodiments thereof, taken together with the drawings in which:

### BRIEF DESCRIPTION OF THE DRAWINGS

FIG. 1 is a block diagram that schematically illustrates a Dynamic Random-Access Memory (DRAM) device comprising an analog refresh loop, in accordance with an embodiment of the present invention;

FIG. 2 is a block diagram that schematically illustrates the architecture of a DRAM device comprising an analog refresh loop with greater detail, in accordance with an embodiment of the present invention;

FIG. 3 is a block diagram that schematically illustrates an analog Arithmetic-Logic-Unit (aALU) circuit, in accordance with an embodiment of the present invention;

FIG. 4 is a block diagram that schematically illustrates a Dual-Reference aALU circuit, in accordance with an embodiment of the present invention;

FIG. 5 is a Write Timing Diagram that schematically illustrates the waveforms of a Write sequence, in accordance with an embodiment of the present invention;

FIG. 6 is a Refresh Timing Diagram that schematically illustrates the waveforms of a Refresh sequence, in accordance with an embodiment of the present invention;

FIG. 7 is a functional-level block diagram that schematically illustrates the operation of a Voltage-Ratio Amplifier used in the aALU of FIG. 4, in accordance with an embodiment of the present invention;

FIG. 8A is a block diagram that schematically illustrates a Log Amplifier used for implementing the Voltage-Ratio Amplifier of FIG. 7, in accordance with an embodiment of the present invention;

FIG. 8B is a block diagram that schematically illustrates an Anti-Log Amplifier used for implementing the Voltage-Ratio Amplifier of FIG. 7, in accordance with an embodiment of the present invention;

FIG. 9 is a flowchart that schematically illustrates a method for analog-only refresh of a multi-level DRAM In accordance with an embodiment of the present invention.

FIG. 10 is a block diagram that schematically illustrates two grouped arrays in a DRAM device comprising an analog refresh loop, in accordance with an embodiment of the present invention; and

FIG. 11 is a block diagram that schematically illustrates a six-bank DRAM device comprising an analog refresh loop, in accordance with an embodiment of the present invention.

### DETAILED DESCRIPTION OF EMBODIMENTS

### Overview

Dynamic Random Access Memory (DRAM), in which data is stored on a capacitor (“storage capacitor”), is crucial for modern computing, serving as the primary type of memory in most devices due to its cost-effectiveness and high storage capacity. DRAM with storage capacities beyond 10 Gb are available today, and the size is expected to further increase in the future.

An inherent drawback of the DRAM technology is the leakage from the capacitor (typically to the substrate). This leakage causes the stored voltage to decay over time. To solve this drawback, DRAM devices often comprise a refresh mechanism, which periodically reads and refreshes all the storage capacitors. Refresh may also be performed as part of user-initiated read operations.

Embodiments of the present invention that are disclosed herein provide apparatuses and methods for an analog DRAM, in which each storage capacitor is configured to store an analog value, representing one or more encoded binary bits of data. In an embodiment, the analog DRAM comprises an analog-only Refresh circuit that reads the analog data stored on target storage capacitors, calculates, using an analog Arithmetic-Logic Unit (aALU), the pre-decay voltage on the storage capacitors, and then accurately refreshes the target storage capacitors, compensating for any fixed bias that may be included in the read analog data.

The high accuracy of the analog refresh loop is useful, for example, for storing multiple bits per storage capacitor with high reliability. The embodiments described below therefore refer mainly to multi-level DRAMs (theoretically, the number of levels—and, hence, the number of stored bits—is not limited; in practice the number is set by parameters like the size of the capacitor, the voltages and the signal-to-noise ratio). The disclosed techniques, however, are not limited to multi-level storage and may also be used in single-level DRAMs that store one bit per capacitor.

The use of an analog-only refresh loop provides significant power savings, as analog to digital and digital to analog conversions are only needed when the DRAM device is, respectively, read or written. In addition, the large serial-out registers that conventional DRAMs use for fast I/O can be saved.

In embodiments, to read a storage capacitor, the analog DRAM device couples a selected target storage capacitor to a common line, which is connected to the aALU. the aALU comprises a first stage that compensates the voltage read from the DRAM cell for attenuation that occurs due to charge sharing between the storage capacitor and the common line.

For improved accuracy, in some embodiments to be disclosed below, each column of DRAM storage capacitors (or, more precisely, each group of DRAM storage capacitors in each DRAM column) comprises one or more reference storage capacitors that store preset reference voltages. In an embodiment, a group of DRAM cells, including the (one or more) reference storage capacitors, is read in a sequence. The one or more reference storage capacitors are read first, and their voltages are corrected by the first aALU stage and stored in one or more corrected-reference voltage capacitors. Each of the next Data storage capacitors is, in turn, read, and its voltage is corrected by the first aALU stage and stored in a corrected data voltage capacitor.

In embodiments, the aALU comprises a second stage, which calculates the pre-decay voltage of the data storage capacitor according to the voltages stored on the corrected data voltage capacitor and on the one or more corrected-reference voltage capacitors. In an embodiment, the aALU estimates the decay according to the decay of the reference storage cells; in some embodiments, the decay of the difference between two reference voltages is used to estimate the decay of the target data storage capacitor.

In an embodiment, the second stage of the aALU comprises a non-linear voltage-ratio amplifier. In some embodiments, the voltage-ratio amplifier comprises log and anti-log circuits; in other embodiments, the voltage-ratio amplifier comprises voltage controlled variable resistors. Other embodiments of the voltage-ratio amplifier are disclosed in the System Description below.

In some embodiments, as part of the process of deriving the refresh voltage from the read voltage, the aALU can also compensate for Process-Voltage-Temperature (PVT) variations, i.e., process variations affecting the DRAM device, variations associated with the supply voltage of the DRAM device, and/or variations associated with the temperature of the DRAM device. PVT compensation can be performed, for example, as part of the Built-In-Self-Test (BIST) procedure of the device, and/or during production.

### System Description

Multilevel Dynamic Random-Access Memories (DRAMs), wherein each storage capacitor may store more than one bit of information, have been suggested in the past. While potentially providing higher storage density, multi-level storage presents a challenge; in particular, if a multi-level charge is to be refreshed, using an analog to digital followed by a digital to analog processes, a huge amount of energy may be consumed. Embodiments that are disclosed herein use pure-analog refresh cycles that do not involve analog to digital or digital to analog conversion, and do not disrupt the stored data (e.g., the worst-case refresh inaccuracy is guaranteed not to change the digital value of the stored data). Digital to Analog (DAC) and Analog to Digital (ADC) converters are not needed in the sub-system analog-domain level and are used only for interfacing the analog domain to the system-level digital domain. The large digital output registers that conventional DRAMS have are not needed.

### Nibbles and Words

In embodiments, a multilevel DRAM cell stores more than one bit of data; for example, if the noise level is such that eight levels can be safely used (e.g., the distance between the storage capacitors' voltages for any two adjacent levels is safely below the maximum expected noise), each DRAM cell can store three data bits.

The group of bits that are stored in a DRAM cell is referred to herein below as a Nibble (not to be confused with strictly 4-bit Nibbles that are often used in the industry). In an example embodiment, the nibble size is eight bits.

The typical width of a digital DRAM word, on the other hand, may be 4, 8 or 16 bits (or more, when error-correction code are added to each word). In other examples, the word size may be less that the nibble size; in an example, an 8-bit nibble can store a pair of 4-bit I and Q values in a communication system.

The discrepancy in width may be addressed by a plurality of techniques, which are beyond the scope of the present disclosure. For example, to store a 16-bit word in 4-bit nibbles, the digital input may be split to four nibbles, that are input to four identical 16-level DRAMs; the digital output is then a concatenation of the nibbles output from the four 16-level DRAM cells.

In the descriptions below, we will ignore the discrepancy between word and nibble sizes and describe nibble-size DRAM devices only. The disclosed techniques, however, are in no way limited to Nibble-width data words in which the data word size is the same as the number of bits stored in each DRAM Cell; in embodiments, any other suitable data word size may be used.

### Rows, Columns and Groups

Similarly to common DRAM techniques and terminology, we assume below that the DRAM comprises one or more DRAM Banks; each DRAM bank comprises horizontal rows, which are connected to the gates of respective rows of select transistors. Vertically, each DRAM bank comprises Columns, which are further divided to vertical Groups; each Group connects to the sources of a vertical group of select transistors. The groups are connected to the respective columns via group-select devices.

For ease of comprehension, the vertical and horizontal orientations defined above may change in some of the figures below, which are not necessarily layout-oriented (we will denote the orientation in the descriptions).

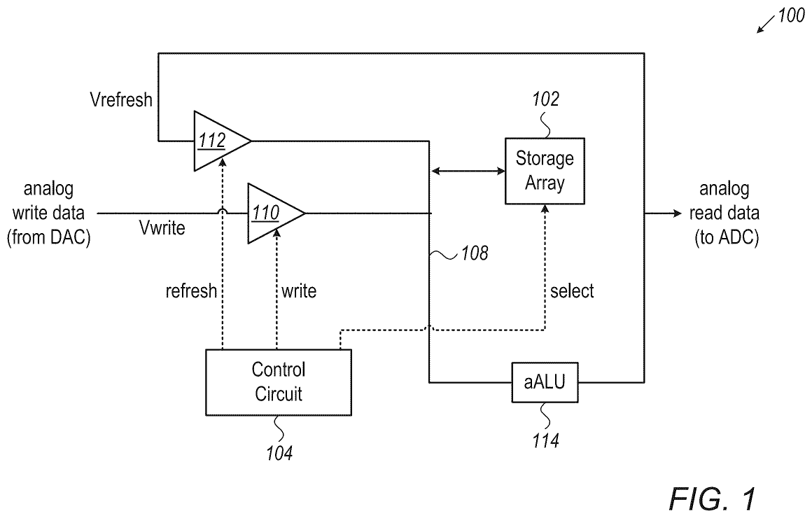

FIG. 1 is a block diagram that schematically illustrates a Dynamic Random-Access Memory (DRAM) device 100, in accordance with an embodiment of the present invention. DRAM 100 comprises a Storage Array 102, which, in turn, comprises a plurality of DRAM cells, each DRAM cell comprising a storage capacitor that is charged to a voltage level representing a multi-bit digital word. In embodiments, at any given time, some of the DRAM cells (referred to as “Data DRAM Cells”) may store DRAM data, while other DRAM cells (referred to as “Reference DRAM Cells”) may store reference data. In some embodiments, the division to Data DRAM cells and Reference DRAM Cells is fixed; for example, in an embodiment, the Storage Array comprises a matrix of rows and columns (that are further divided into groups); the center DRAM cell of each group is a Reference DRAM Cell (but, in embodiments, the Reference DRAM Cells is read before the Data-DRAM Cells are read). In other embodiments, the division into Data DRAM Cells and Reference DRAM Cells may change dynamically.

DRAM 100 further comprises a Control Circuit 104, which controls Write, Read and Refresh operations of the DRAM cells. In an embodiment, the Control Circuit controls switches (e.g., transistors; not shown) of Storage Array 102; the switches are configured to selectively couple the storage capacitors to a Data-Line 108. In embodiments, various coupling circuits may be used, including, for example, a combination of column row and group selection.

For a DRAM write operation, the Control Circuit activates a buffer 110, which transfers a Write voltage level V_{write} (e.g., a voltage generated by a Digital to Analog converter, (DAC)) to the Data-Line 108; the Control Circuit further connects a selected Data DRAM Cell to the Data-Line, and, thus, the respective storage capacitor is charged according to the Write Voltage.

For a DRAM Refresh operation, the Control Circuit first reads a target DRAM Cell (Read operation will be described below), and then activates a buffer 112, which transfers a Refresh voltage level V_{refresh} (to be described below) and connects a selected Data DRAM Cell to the Data-Line; thus, the selected target storage capacitor is charged according to the Refresh Voltage.

To read the charge stored on a storage capacitor, Control Circuit 104 selects the corresponding DRAM cell, but does not activate any of buffers 110 and 112. As a result, charge sharing between the charge stored on the storage capacitor and the charge stored on the Data-Line 108 takes place (in an embodiment, prior to reading, the Control Circuit may precharge the Data-Line to a preset precharge voltage). We will refer hereinbelow to the voltage on the data-line following the Read operation as V_{read}.

DRAM 100 further comprises an Analog Arithmetic Logic Unit (aALU) 114, which is configured to receive the V_{read} voltage and, responsively, to generate the V_{refresh} voltage. In embodiments, the Refresh voltage V_{refresh} is such that when written (by Control Circuit 104) to a storage capacitor, the original charge on the storage capacitor prior to the Read operation will be closely restored. In some embodiments, to generate V_{refresh}, the Control Circuit also reads one or more Reference DRAM Cells, and the aALU generates V_{refresh} responsively to the voltage V_{read} when a Reference DRAM cell is read (this will be described in detail below).

In an embodiment, the generation of V_{refresh} by aALU 114 comprises analog operations only, for higher speed and better accuracy (since the DRAM should retain data integrity over long periods, good accuracy of a read-refresh cycle such as that achieved by analog-only operations is crucial).

In embodiments, for DRAM Read operations, the output of aALU 114 is coupled to an Analog-to-Digital Converter (ADC), which translates the multilevel voltage to a digital word.

The configuration of DRAM device 100, illustrated in FIG. 1 and described herein above is cited by way of example. Other configurations may be used in alternative embodiments. For example, in an embodiment, a plurality of DRAM cells are written and read at the same time, over a plurality of Data-Lines and using an aALU that is configured to generate multiple V_{refresh} voltages concurrently.

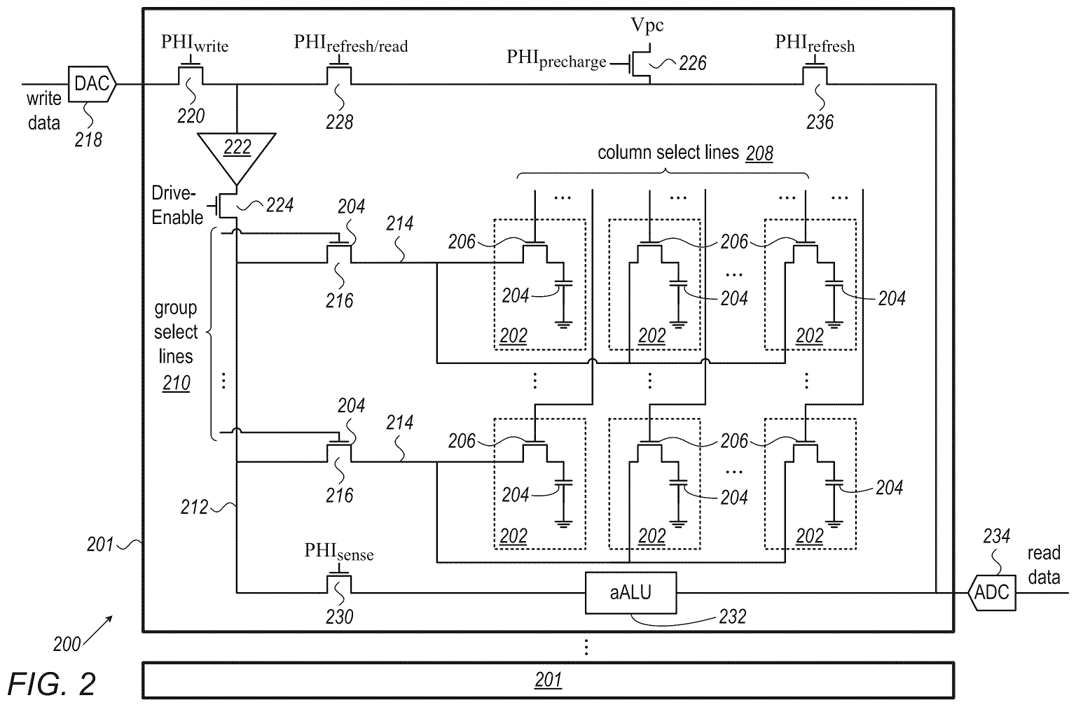

FIG. 2 is a block diagram that schematically illustrates the architecture of a DRAM device 200, in accordance with an embodiment of the present invention. According to the example embodiment illustrated in FIG. 2, DRAM device 200 comprises a two-dimensional array of DRAM-Cells 202, each DRAM cell comprising a Storage-Capacitor 204 and a Select-Transistor 206. The two-dimensional array comprises a plurality of DRAM-Columns 201, each Columns 201 comprising a plurality of Groups 214. It should be noted that the orientation in FIG. 2 is mixed—vertical Groups 214 are drawn horizontally, while the vertical Column 201 are drawn vertically. In embodiments, both the groups and the column are vertical, using different metal layers.

Capacitors 204 may be gate-source capacitors, Metal-Insulator-Metal (MIM) capacitors or intrinsic capacitors that are used in some modern capacitor-less technologies are used.

A Control Circuit (e.g., Control Circuit 104, FIG. 1) is configured to drive a group of Column-Select lines 208 and a group of Group-Select lines 210. To couple the X^{th} storage capacitor to a Data-Line 212 (wherein X designates the column number), the Control Circuit activates (e.g., sets to logic high) the X^{th} Column-Select line and deactivates all other Column-Select lines (e.g., sets to logic-low). At the same time, the Control Circuit activates one of Group-Select lines 210 (according to the group of the X^{th} column) and deactivates all other Group-Select lines.

Each Column-Select line 208 is connected to the gates of a single Select-Transistor 206 of DRAM-Column 201. When a Column-Select line is activated, the selected storage capacitor will be coupled to a Group-Line 214. Each Group-Select line 210 is connected to the gate of a Group-Select transistor 216, which is configured to connect a selected Group-Line 214 to Data-Line (Column) 212.

To write data into a selected one of DRAM-Cells 202, a Digital to Analog converter (DAC) 218 first converts the data to be written (as explained above, we assume nibble-size data) into an analog value. The analog value is forwarded, through a transistor 220, to a Buffer (e.g., a unity gain Amplifier) 222 and a Drive-Enable transistor 224, to Data-Line 212, and, from there, through a Group-Select transistor 216 (that is selected according to an active Group Select line 210) and through a Select-Transistor 206 (that is selected according to an active Column-Select line 208), to the selected Storage-Capacitor 204. The voltage on the Bit-Line 210 will, thus, charge the selected Storage-Capacitor.

To read data from a selected one of DRAM-Cells 202, a Precharge transistor 226 charges (or discharges) Data-Line 212, through a Refresh/Read Transistor 228, Buffer 222 and Drive-Enable Transistor 224. The Control Circuit will activate one of Group-Select lines 210, but will not activate any of Column-Select lines 208; consequently, a selected one of Group-Lines 214 will precharge, through a respective Group-Select Transistor 216. At a subsequent clock phase, the Control Circuit will activate one of Column-Select lines 208, connecting the Storage-Capacitor of the selected DRAM-Cell to the respective Group-Line 214 (through one of Select-Transistors 206), and, thence, to Data-Line 212 (through the activated Group-Select transistor 216).

In embodiments, the source voltage of Precharge transistor 226 may vary (e.g., set in device calibration), allowing precharge or predischarge to any voltage.

The coupling of the selected Storage-Capacitor to the Group-Line 214 and Data-Line 212 will result in charge sharing, reducing the storage capacitor voltage (or, more accurately, the difference between the precharge voltage and the storage capacitor voltage) by a ratio according to the capacitance ratio:

$${V}_{readout} = {V}_{pc} + ( {V}_{sc} - {V}_{pc} ) * {C}_{sc} / ( {C}_{sc} + {C}_{r l} + {C}_{dl} + {C}_{p} )$$

Wherein:
V_{readout} is the voltage on the Data-Line after charge sharing;
V_{pc} is the precharge voltage;
V_{sc} is the initial voltage on the Storage-Capacitor (prior to the Charge-Sharing;
C_{sc} is the capacitance of the Storage-Capacitor;
Cᵣₗ is the capacitance of the selected Group-Line 214;
C_{dl} is the capacitance of the Data-Line 212; and
Cₚ is the additional parasitic capacitance (e.g., the capacitance of transistors 206 and 216, and others).

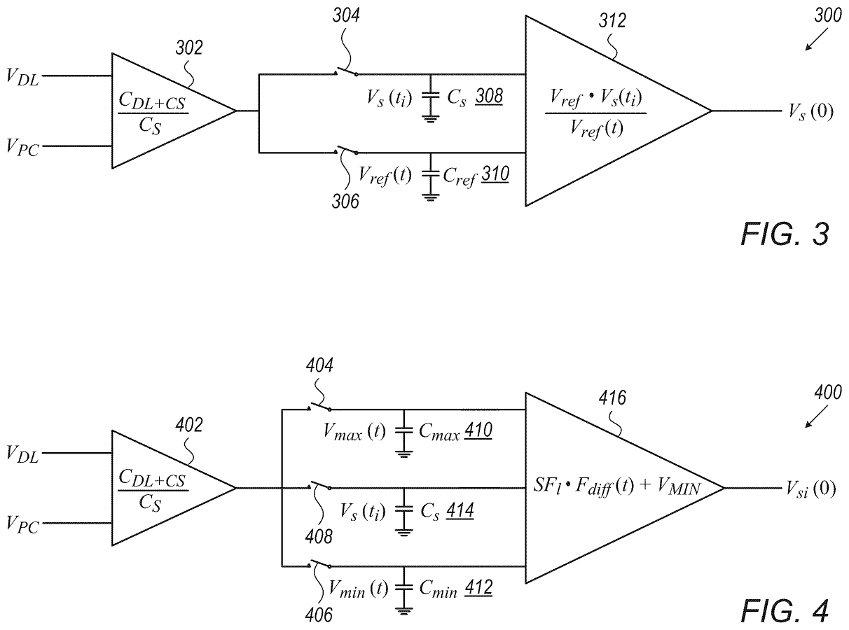

The voltage on Data-Line 212 after charge-sharing is input, through a Sense Transistor 230, to an Analog Arithmetic-Logic Unit (aALU) 232, which is configured to compensate for the charge-sharing attenuation and for the decay of the stored charge over time (two example embodiments of aALU 232 will be disclosed below, with reference to FIGS. 3 and 4). The voltage that aALU 232 generates is input to an Analog to Digital Converter (ADC) 234, which is configured to convert the aALU output to a digital Nibble, representing the output of the DRAM.

To refresh a target DRAM-Cell, the Control Circuit first executes a Read cycle as described above, and then, at a subsequent clock phase, routes the output of aALU 232, through a Refresh Transistor 236, Refresh/Read Transistor 228, Buffer 222 and Drive-Enable transistor 224, to Data-Line 212, and, thence, through a selected one of Group-Select Transistors 216 and through a selected one of Column-Select Transistors 206, to the target Storage-Capacitor of the DRAM-Cell being refreshed.

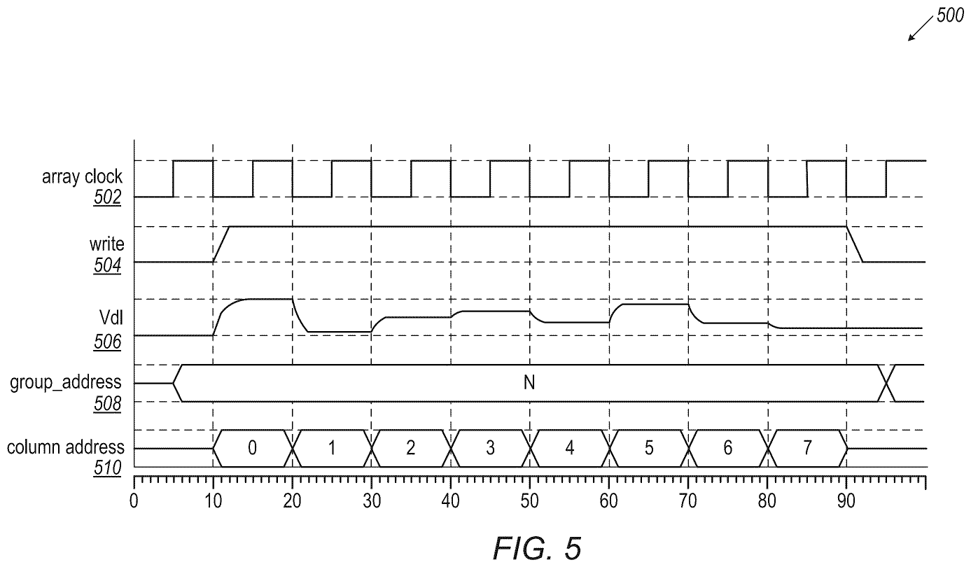

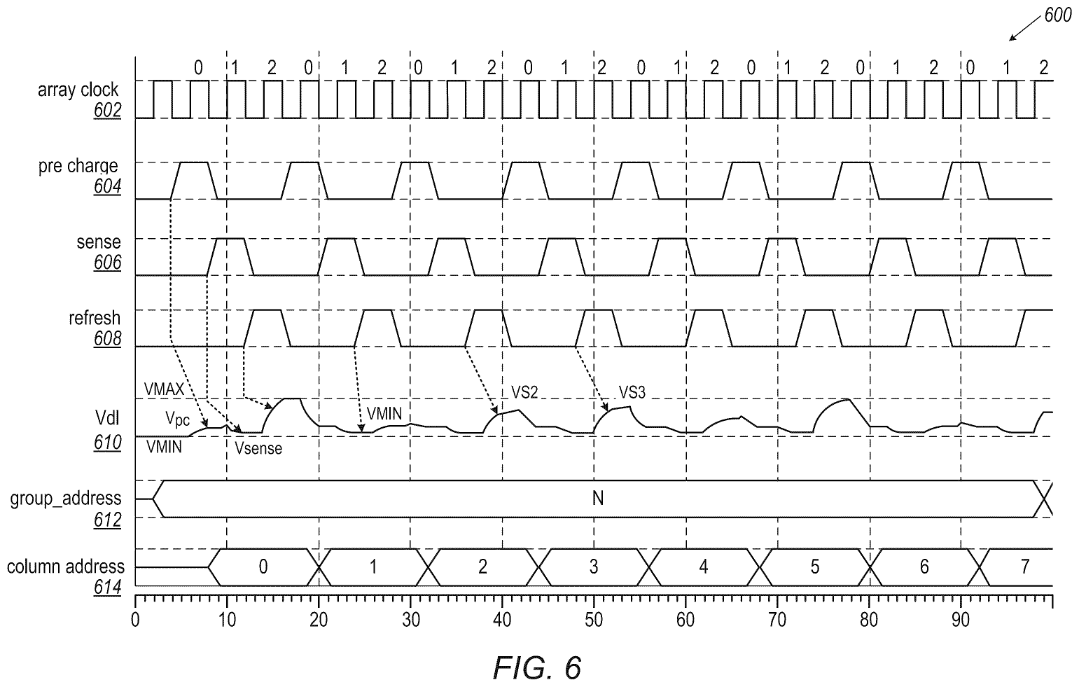

It should be noted that Control Circuit 104 is configured to activate the switching transistors 220, 228, 236, 224, 230, 206, 216 and the precharge transistors 226 according to the functionality described above and according to a timing regime that, on one hand, guarantees sample charge time and, on the other hand, avoids contention. Some timing examples will be described below, with reference to FIGS. 5 and 6.

In some embodiments, each DRAM-Group is written/read/refreshed sequentially. Each DRAM-Group comprises one or more Reference-DRAM Cells that are read in timewise proximity (but prior to) the Data-DRAM Cells (e.g., if the DRAM-Group is accessed from left to right, the Reference-DRAM-Cells may be the leftmost DRAM Cells of the group; in another example, the Reference-DRAM-Cells may be located at the center of the DRAM-Group or elsewhere in the group, but accessed first).

This allows the aALU to accurately compensate for the decay of the Storage-Capacitors (as will be explained below, with reference to FIGS. 3 and 4).

It should be noted that DRAM Device 200 comprises other circuits that are not described hereinabove, such as column row and group decoders and, sometimes, error detection and correction circuitry.

The configuration of DRAM device 200, illustrated in FIG. 2 and described herein above is cited by way of example. Other configurations may be used in alternative embodiments. For example, in some embodiments, Buffer 222 is not needed. In other embodiments, the DRAM device comprises a plurality of banks; all banks are continuously refreshed but, for read and write operations, a selected bank only is activated.

### Example Analog ALU Configurations

FIG. 3 is a block diagram that schematically illustrates an aALU circuit 300, in accordance with an embodiment of the present invention. This aALU can be used, for example, to implement aALU 114 (FIG. 1) or aALU 232 (FIG. 2).

The aALU of FIG. 3 comprises a Linear Amplifier 302, a Vₛ-Sampling-Transistor 304, a V_{ref}-Sampling-Transistor 306, a Vₛ-Storage-Capacitor 308, a V_{ref}-Storage-Capacitor 310, and a Voltage-Ratio Amplifier 312.

As described above, after charge-sharing, the voltage on the storage capacitor (as read on the Data-Line) is attenuated:

$${V}_{DL} = {V}_{PC} + \frac{( {V}_{S} - {V}_{PC} ) * {C}_{S}}{{C}_{S} + {C}_{DL}} \qquad ( 1 )$$

Wherein:
V_{DL} is the voltage on the Data-Line after charge sharing;
V_{PC} is the precharge voltage;
V_{S} is the voltage on the storage capacitor prior to the charge-sharing;
C_{S} is the capacitance of the Storage Capacitor; and
C_{DL} is the combined capacitance of the Data-Line, Row-Line, Group-Line and any parasitic capacitances that share the charge.

Linear Amplifier 302 is configured to compensate for that attenuation, and amplifies the difference V_{S}−V_{PC} by (C_{DL}+C_{S})/C_{S}, and then subtracts V_{pc}, to get V_{S}.

The purpose of Voltage-Ratio Amplifier 312 is to compensate for the charge decay over time. Towards that end, each DRAM-Group comprises a Reference-Storage Cell, that is charged to a known voltage level V_{REF}. We assume that the decay ratios of both the Data-DRAM-Cell and the Reference-DRAM Cell are identical. This assumption should be accurate if the structure and the decay time of the Reference DRAM Cell and the Data-DRAM-Cell are closely matched; the first assumption is based on the identical drawn layout and geometric proximity of the cells; the latter assumption is justified because the complete row (including all groups thereof) is precharged and then read, in uninterrupted sequences.

When the voltage on the Data-Line V_{DL} is V_{ref} (the voltage after the Reference-DRAM-Cell is read), V_{ref}-Sampling-Transistor 306 turns on, and V_{ref}-Storage-Capacitor 310 stores the attenuation-compensated voltage V_{ref-s}. When the voltage on the Data-Line is V_{Si} (the voltage after each of the Data-DRAM-Cells is read), Vₛ-Sampling-Transistor 304 turns on, and V_{ref}(t)-Storage-Capacitor 310 stores the attenuation-compensated voltage Vₛ (ti).

The voltage on both the Data-Storage-Capacitor and the Reference-Storage-Capacitor start to decay after they are written, therefore, we designate the voltages on capacitors 308 and 310 as Vₛ and V_{ref}(t), respectively (capacitor 310 is configured to retain the compensated reference voltage while the data DRAM cells of the group are read).

Assuming an exponential decay with an equal time constant, and assuming the same decay time for both the Reference and the Data DRAM Cells, we get:

$${V}_{ref} ( t ) = {V}_{REF} * {e}^{\frac{- t}{τ}} \qquad ( 2 )$$

Where V_{REF} is the initial voltage on the Reference-DRAM-Cell, and:

$${V}_{S} ( {t}_{i} ) = {V}_{Si} ( 0 ) * {e}^{\frac{- t}{τ}} \qquad ( 3 )$$

Where V_{SI}(0) is the initial voltage on the i^{th} Data-DRAM-Cell.

Voltage-Ratio Amplifier 312 is configured to compensate for the decay, and generate V_{Si}(0) by multiplying V_{REF} by the ratio between the voltages on capacitors 308 and 310:

$${V}_{Si} ( 0 ) = \frac{{V}_{REF} * {V}_{S} ( {t}_{i} )}{{V}_{ref} ( t )} \qquad ( 4 )$$

The configuration of aALU 300 illustrated in FIG. 3 and described hereinabove is relatively simple, requiring a single reference voltage V_{REF} (in an example embodiment, V_{REF} is set to half the value of the maximum V_{S}). The noise resilience of aALU 300, however, is inferior relative to the two-reference-voltages embodiments, to be disclosed below.

FIG. 4 is a block diagram that schematically illustrates a Dual-Reference aALU circuit 400, in accordance with an embodiment of the present invention. Dual-Reference aALU circuit 400 can also be used, for example, to implement aALU 114 (FIG. 1) or aALU 232 (FIG. 2).

The Dual-Reference aALU uses two reference voltages, that are stored in two Reference-DRAM Cells in the same DRAM Group. In an embodiment, a first Reference Cell, denoted MINV-DRAM-Cell, is charged to a V_{MIN} voltage level that is equal to the minimum operational voltage of the DRAM-Cell, and a second first Reference Cell, denoted MAXV-DRAM-Cell, is loaded to a voltage level V_{MAX} that is equal to the maximum operational voltage of the DRAM-Cell. Following the charging of the reference DRAM-Cells, the reference voltages will decay with time; we denote the temporal value of the voltages as Vₘᵢₙ(t) and Vₘₐₓ(t), respectively. We further denote Vₘᵢₙ(0) as V_{MIN}, and Vₘₐₓ(0) as V_{MAX}.

Like in aALU 300, a Linear Amplifier 402 amplifies the difference between the voltage level read from the Data-Line 212 (FIG. 2) and the Precharge Voltage by the reciprocal of the charge sharing attenuation, thus, compensating for the attenuation. A switch 404 samples the attenuation-compensated value of Vₘₐₓ(t), which is then stored on a Cₘₐₓ Capacitor 410, a switch 406 samples the attenuation-compensated value of Vₘᵢₙ(t), which is then stored on a Cₘᵢₙ Capacitor 412, and a switch 408 samples, for every one of the Data-DRAM Cells, the attenuation—compensated value of V_{Si}(t)−the i^{th} Data-DRAM Cell in the DRAM Group. The compensated value of V_{Si}(t) is stored on a C_{S} capacitor 414.

Assuming an exponential decay with an equal time constant, and assuming the same decay time for the two Reference-DRAM Cells and the Data-DRAM-Cell, we get:

$${V}_{max} ( t ) = {V}_{MAX} * {e}^{\frac{- t}{τ}} + n ( t ) , \qquad ( 5 )$$

$${V}_{min} ( t ) = {V}_{MIN} * {e}^{\frac{- t}{τ}} + n ( t ) , \qquad ( 6 )$$

$${V}_{S} ( {t}_{i} ) = {V}_{Si} ( 0 ) * {e}^{\frac{- t}{τ}} + n ( t ) \qquad ( 7 )$$

Wherein:
V_{MAX} is the initial voltage on the MAXV-DRAM-Cell;
V_{MIN} is the initial voltage on the MINV-DRAM-Cell;
V_{Si}(0) is the initial voltage on the i^{th} Data-DRAM-Cell;
and:
n(t) is a noise that is added to the three voltages (the noise is, in a first approximation, equal).

We now define a Decay-Compensation factor SF:

$$SF = \frac{{V}_{MAX} - {V}_{MIN}}{{V}_{max} ( t ) - {V}_{min} ( t )} \qquad ( 8 )$$

And a difference signal Vdiff:

$${V}_{diff} ( t ) = {V}_{Si} ( t ) - {V}_{min} ( t ) . \qquad ( 9 )$$

To restore V_{Si}(0), aALU 400 further comprises a Voltage-Ratio Amplifier 416, which is configured to compensate for the decay, and generate V_{Si}(0):

$${V}_{Si} ( 0 ) = {V}_{diff} ( t ) * SF + {V}_{MIN} \qquad ( 10 )$$

Thus, according to the example embodiment illustrated in FIG. 4, aALU 400 can compensate for equal noise that is induced on the sampling capacitors, to accurately reconstruct the initial voltage stored in the Data-DRAM-Cells.

The configuration of Dual-Reference amplifier 400, illustrated in FIG. 4 and described above, and the use of two reference voltages that are in proximity to each other and to the target DRAM cell, provides for high accuracy, mitigating common noise and providing resiliency to (i) process variation affecting the DRAM device, (ii) variations associated with a supply voltage of the DRAM device, and (iii) variations associated with a temperature of the DRAM device.

### Timing Diagrams

FIG. 5 is a Write Timing Diagram 500 that schematically illustrates the waveforms of a Write sequence, in accordance with an embodiment of the present invention. Timing Diagram 500 illustrates the writing of an 8-column group in a DRAM, having a Dual-Reference-Voltage aALU. A Clock Graph 502 illustrates the waveform of a clock signal, which pulses for every column; a Write Graph 504 illustrates a Write signal, which is high for eight clock cycles; a V_{dl} Graph 506 shows the voltage of the Data-Line; a Group-Address Graph 508 shows the Group address (which does not change); and, a Column-Address Graph 510 illustrates the Column-Select index, which counts from zero to seven.

According to the example embodiment illustrated in FIG. 5, the first Reference-DRAM-Cell, stored at the first column (column 0), is set to a relatively high voltage, V_{MAX}, whereas the second Reference-DRAM-Cell, stored at the second column (column 1) is set to a relatively low voltage, V_{MIN}.

Accordingly, at the first clock cycle (column-address=0), V_{dl} is set to a relatively high level, to charge the first Reference-DRAM-Cell. At the second clock cycle (column-address=1), V_{dl} is set to a relatively low level, to charge the second Reference-DRAM-Cell. In further clock cycles, when the Data-DRAM Cells are written, V_{dl} is set according to the value of the multi-level nibble that is written into the selected DRAM-Cells.

FIG. 6 is a Refresh Timing Diagram 600 that schematically illustrates the waveforms of a Refresh sequence, in accordance with an embodiment of the present invention. Timing Diagram 600 illustrates the refreshing of an 8-column group in a DRAM, having a Dual-Reference-Voltage aALU. A Clock Graph 602 illustrates the waveform of a clock signal. The clock pulses three times for each column. The first pulse, referred to as Phase-0, is used to precharge the Data-Line; the second pulse (Phase-1) is used to read the DRAM-Cells; and the third pulse (Phase-2) is used to write-back the refreshed data into the DRAM-Cell (the phase numbers are indicated above Graph 602).

A Precharge Graph 604 illustrates a Precharge control signal, pulsing at Phase-0, to prepare the Data-Line for a read operation; a Vsense Graph 606 illustrates a Sense control signal, which pulses at Phase-1, to read a DRAM-Cell through the Data-Line and into the aALU; a V_{refresh} Graph 608 illustrates a Refresh control signal, which pulses at Phase-2 and stores the refresh voltage back to the DRAM-Cell.

A V_{dl} Graph 610 illustrates the voltage on the Data-Line, precharged at Phase-0 and then set according to the read voltage at Phase-1, or according to the refresh voltage at Phase-2. Note that in the first two columns, two Reference-DRAM Cells are refreshed, and in the next columns (2 through 7), six data DRAM-Cells, storing various voltage levels are read and then refreshed.

A Group-Address Graph 612 shows the Group address (which does not change); and a Column-Address Graph 614 illustrates the Column-Select index, which counts from zero to seven.

The Write Timing Diagram and the Read and Refresh Timing Diagrams illustrated in FIG. 5, 6 and described above are cited by way of example. Other timing diagrams may be used in alternative embodiments. For example, in an embodiment, the number of columns in a group may be different (typically much higher) than eight. In some embodiments, the number of Data-Reference Cells in a group may be different from two.

### Voltage-Ratio Amplifier Implementations

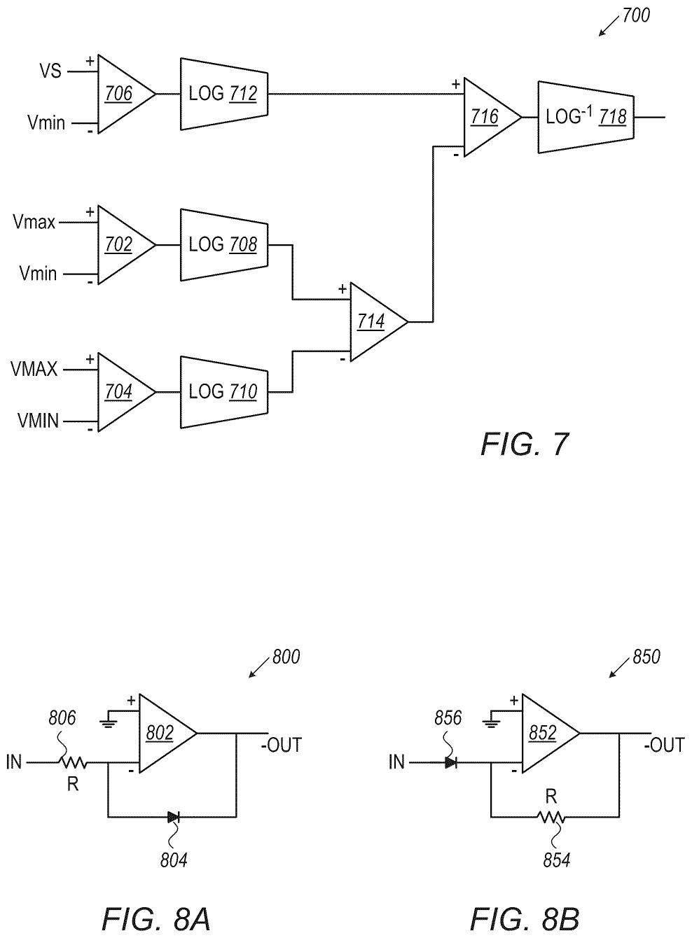

FIG. 7 is a block diagram that schematically illustrates a functional-level block diagram of a Voltage-Ratio Amplifier 700, in accordance with an embodiment of the present invention. This configuration can be used, for example, in Voltage-Ratio Amplifier 416 (FIG. 4). A simplified version of this configuration can be used, for example, in Voltage-Ratio Amplifier 312 (FIG. 3).

Voltage-Ratio Amplifier 700 comprises an example embodiment of Voltage-Ratio Amplifier 416 (FIG. 4), having the same inputs.

As shown above,

$$\begin{matrix}{V}_{S i} ( 0 ) = {V}_{diff} ( t ) * SF + {V}_{MIN} = \\ = ( {V}_{Si} ( t ) - {V}_{min} ( t ) ) * \frac{{V}_{MAX} - {V}_{MIN}}{{V}_{max} ( t ) - {V}_{min} ( t )}\end{matrix} \qquad ( 12 )$$

We use LOG and ANTI-LOG Amplifiers functions to implement multiplications and divisions; a Log Amplifier approximates a LOG function: Output=Log₁₀(Input), at a predefined range and, possibly, with scaling. An Anti-Log Amplifier implements the inverse function: OUT=10^{Input} (the base 10 used hereinabove is an example; other suitable bases may be used in alternative embodiments).

Using the Log function, we can rewrite equation (12) as:

$$Log ( {V}_{Si} ( 0 ) ) = Log ( {V}_{Si} ( t ) - {V}_{min} ( t ) ) ++ Log ( {V}_{MAX} - {V}_{MIN} ) - Log ( {V}_{max} ( t ) - {V}_{min} ( t ) )$$

A Linear Amplifier 702 is configured to output the difference V_{MSB}−V_{LSB}; A Linear Amplifier 704 is configured to output the difference Vₘₐₓ−Vₘᵢₙ, and a Linear Amplifier 706 is configured to output the difference V_{S}−V_{lsb}.

A Log-Amplifier 708 then generates LOG(V_{MAX}−V_{MIN}); a Log-Amplifier 710 generates LOG(Vₘₐₓ−Vₘᵢₙ), and a Log-Amplifier 712 generates LOG(V_{S}−Vₘᵢₙ).

A Linear amplifier 714 subtracts the output of Log Amplifier 710 from the output of Log Amplifier 708, to generate Log(V_{MAX}−V_{MIN})−Log (Vₘₐₓ(t)−Vₘᵢₙ(t)), and a Linear Amplifier 716 adds the output of Log Amplifier 712 to the output of Linear Amplifier 714, to generate:

$$Log ( {V}_{MAX} - {V}_{MIN} ) - Log ( {V}_{msb} ( t ) - {V}_{min} ( t ) ) .$$

Lastly, an Anti-Log Amplifier 710 outputs V_{Si}(0).

As can be observed, Voltage-Ratio Amplifier 700 will operate correctly also if the Log and Anti-Log amplifiers output negative values (−Log and −Log⁻¹).

FIG. 8A is a block diagram that schematically illustrates a Log Amplifier 800, in accordance with an embodiment of the present invention. Log Amplifier 800 can be used, for example, to implement amplifiers 708, 710 and 712 (FIG. 7). The implementation is based on the voltage-current relationship of forward-biased diodes:

$$I = {I}_{S} * {e}^{{V}_{D} / ( {nV}_{T} )}$$

Wherein I_{S} is the saturation current, V_{T} is a forward threshold voltage, V_{D} is the forward voltage, and I is the current through the diode.

It follows that, at a given range and to a given accuracy, the forward voltage on the diode is a log function of the voltage.

Log-Amplifier 800 comprises a negative-feedback Operational Amplifier 802; the virtual ground (negative input) is connected to the output of the operational amplifier through a Diode 804, and, through a Resistor 806, to the Input of the Log-Amplifier circuit (Note that the output of Log Amplifier 800 is negated).

FIG. 8B is a block diagram that schematically illustrates an Anti-Log Amplifier 850, in accordance with an embodiment of the present invention. Anti-Log Amplifier 850 can be used, for example, to implement amplifier 718 (FIG. 7). Anti-Log Amplifier 850 comprises a negative-feedback Operational Amplifier 852; the virtual ground (negative input) is connected to the output of the operational amplifier through a Resistor 854, and, through a Diode 856, to the Input of the Anti-Log-Amplifier circuit (Note that the output of Anti-Log Amplifier 850 is negated).

Both Log-Amplifier 850 and Anti-Log Amplifier 852 should be designed so that the operating range of Diodes 804, 854 will be in the Log region of the diodes, with I safely lower than I_{S}.

The configuration of Voltage-Ratio Amplifier 700, including Log-Amplifier 800 and Anti-Log Amplifier 852 is cited by way of example. Other configurations may be used in alternative embodiments. For example, in an embodiment, signal multiplication is done using a variable-gain amplifier. In another embodiment, Voltage Dependent Resistors (VDRs) are used.

### Refresh Method Description

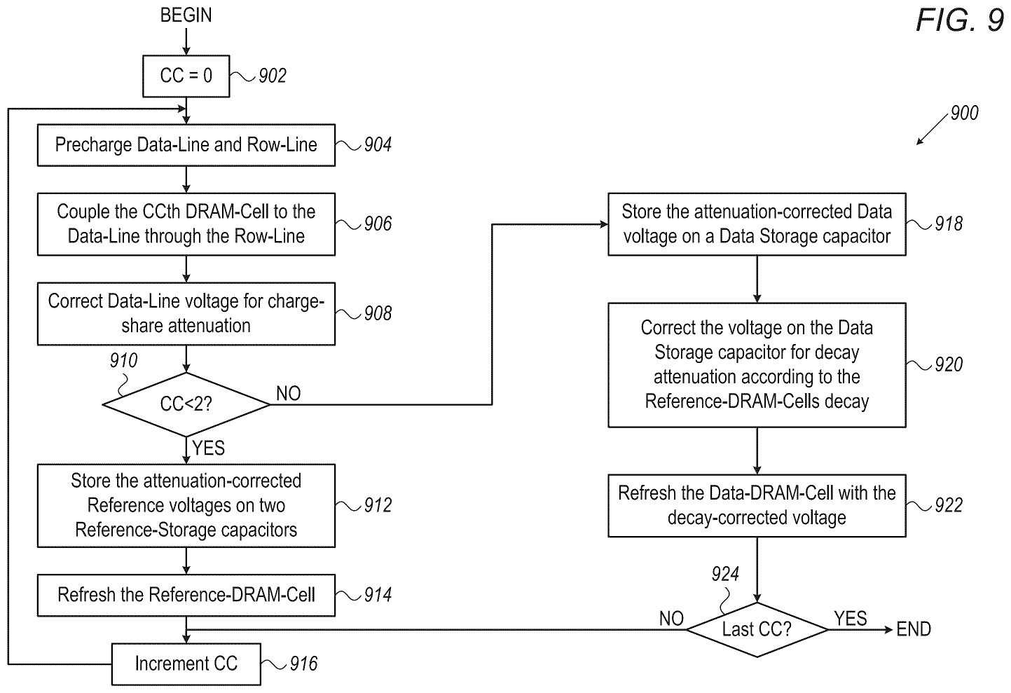

FIG. 9 is a flowchart 900 that schematically illustrates a method for analog-only refresh of a multi-level DRAM In accordance with an embodiment of the present invention. The flowchart is executed by Control Circuit 104 and aALU 114 (FIG. 1).

The flowchart starts at a Clear Column Counter operation 902, wherein the Control Circuit clears (sets to zero) a Column Counter (CC), to point at the first column of the DRAM array (column 0). (It is assumed that a Group Counter has already been set to point at a selected group; the Group Counter remains unchanged during the operation of Flowchart 900 and will be ignored hereinbelow.)

Next, at a Precharge operation 904, the Control Circuit will precharge the Data-Line and, through a Group-Select transistor 216, a selected Group Line 214 (FIG. 2). Now, at a Couple DRAM-Cell operation 906, the Control Circuit will activate the CC^{th} Column-Select line 208 (FIG. 2), coupling the storage capacitor 204 of the CC^{th} DRAM-Cell to the Group-Line and, through the Group-Select transistor, to the Data-Line.

The flowchart now enters a Correct-for-Charge-Sharing-Attenuations operation 908, wherein the aALU amplifies the difference between the Data-Line voltage and the Precharge voltage by the reciprocal of the attenuation of the voltage on the storage capacitor as a result of charge sharing with the combined charge of the Data-Line and the Group-Line (and any parasitic capacitance). The corrected voltage will be stored in a further operation.

Next, at a Check-CC-Less-Than-2 operation 910, The Control Circuit checks if the CC counter is below the value of 2 (that is—the CC points to one of the two Reference-DRAM-Cells). If so, the flowchart enters a Store-Corrected-Reference Voltages operation 912, wherein the Control Circuit stores the attenuation-corrected voltages of the two Reference DRAM Cells in two storage capacitors, and then enters a Refresh-Reference-DRAM-Cells operation 914, wherein the Control Circuit refreshes the two Reference-DRAM-Cells with the predefined reference voltage levels. The attenuation-corrected reference voltages that were stored (in operation 912) on capacitors will be used in further operations, to estimate the decays of further storage capacitors 204 (FIG. 2) and, thus, compensate for additive noise.

After operation 914, the flowchart, at an Increment-CC operation 916, increments the CC counter, and then reenters operation 904, to precharge the Data-Line and Group-Line, and to read the next DRAM Cell.

If, in operation 910, the CC has reached or passed the value of 2, The flowchart enters a Store-Corrected-Data Voltage operation 918, wherein the Control Circuit stores the attenuation-corrected voltages of the Data-DRAM Cell at column CC, in a storage capacitor. The Flowchart now enters a Correct-for-Decay operation 920, wherein the ALU generates a refresh voltage that corrects the attenuation-corrected Data-DRAM-Cell voltage for decay, under the assumption that the decay time constants of the storage capacitors in the same DRAM Group are closely matched to each other. In an embodiment, the aALU multiplies the attenuation-corrected Data-DRAM-Cell voltage (that was stored in a capacitor, in operation 918) by the reciprocal of the decay of the difference between the two Reference voltages, from the initial difference to the difference between the voltages on the Reference-Storage capacitors that were stored in operation 912.

Next, at a Refresh Data-DRAM-Cell operation 922, the Control Circuit refreshes the Data-DRAM-Cell with the Refresh Voltage generated in operation 920.

After operation 922, the Flowchart, at a Check-Last-CC operation 924, checks if the last CC has been reached (in other words, the last DRAM-Cell in the group has been refreshed). If the last CC value has not been reached yet, the flowchart enters Increment CC operation 916, increments the CC to point to the next column, and then reenters operation 904, to refresh the next DRAM-Cell.

Thus, according to the example flowchart illustrated in FIG. 9, a group of DRAM cells that store analog data along with two reference voltages can be refreshed using analog operations only.

The configuration of flowchart 900, illustrated in FIG. 9 and described herein above, is cited by way of example. Other configurations may be used in alternative embodiments. For example, in some embodiments, only one Reference-DRAM-Cell is used; in other embodiments, more than two Reference-DRAM-Cells may be used, e.g., in an embodiment, every 16^{th} DRAM Cell stores a reference voltage.

### Analog Memory

In some embodiments, the techniques described hereinabove are used to implement an analog-only dynamic memory (analog DRAM). The analog DRAM comprises a plurality of Storage Capacitors 204 (FIG. 2). The Storage Capacitors are configured to store a continuous range of an electric charge, representing a continuously defined analog value.

In some embodiments, the analog DRAM comprises an analog input (e.g., a continuous voltage source); in other embodiments, the output of the analog DRAM is connected to analog circuitry. For example, in an embodiment, the analog DRAM stores a plurality of analog I-Q samples of a communication channel that are input from a communication receiver, and the output of the analog DRAM is connected to a communication transmitter or an analog oscilloscope, for communication channel memory.

### Physical Design Examples

We will next describe the physical design and layout architecture of two example embodiments.

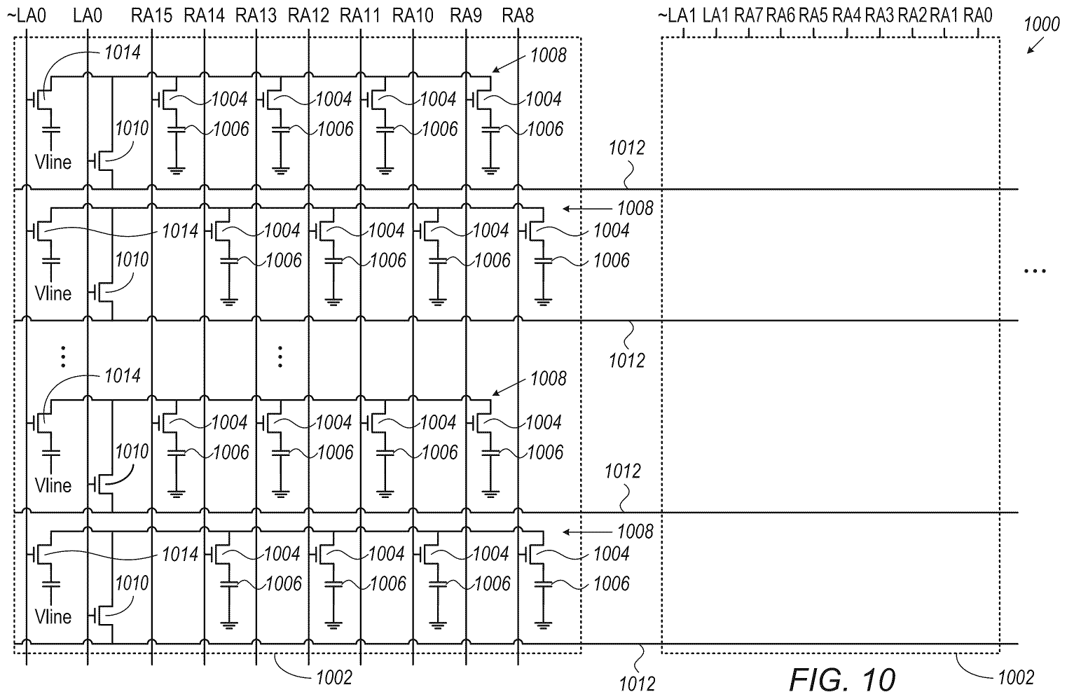

FIG. 10 is a block diagram that schematically illustrates a two-dimensional array 1000 in a DRAM device comprising an analog refresh loop, in accordance with an embodiment of the present invention. The block diagram is layout oriented (but rotated, so that rows are drawn vertical and columns are drawn horizontal), and shows an actual preferred 2-D arrangement of the DRAM cells, comprising memory-groups 1002 (each memory group includes four Groups of four respective columns).

Each Memory-Group comprises an array of Select Transistors 1004 that are coupled to respective Storage Capacitors 1006, and configured to couple the capacitors to horizontally-drawn group lines 1008.

For optimal layout, Select Transistors 1004 and the respective Storage Capacitors 1006 are arranged in a checker-board pattern between horizontal group-lines and vertical select-lines (the latter designated RAi). Group-select transistors 1010 couple the group lines to respective Data-lines 1012. The Group-Select vertical control signals are designated LA0 for the left-most group and LA1 for the second-from-left group (and so on for further groups, if exist).

To minimize leakage from the storage capacitors, non-selected group lines are coupled by transistors 1014 to a preset voltage level V, that is adjusted (e.g., calibrated) to minimize the leakage.

The configuration of Two-Dimensional Array 1000, illustrated in FIG. 10 and described herein above is cited by way of example. Other configurations may be used in alternative embodiments. For example, in some embodiments, the checker-board structure is replaced by a sparser or a denser structure. In an embodiment, transistors 1008 may comprise PMOS transistors (with inverted control polarity), and in another embodiment transistors 1014 are not implemented.

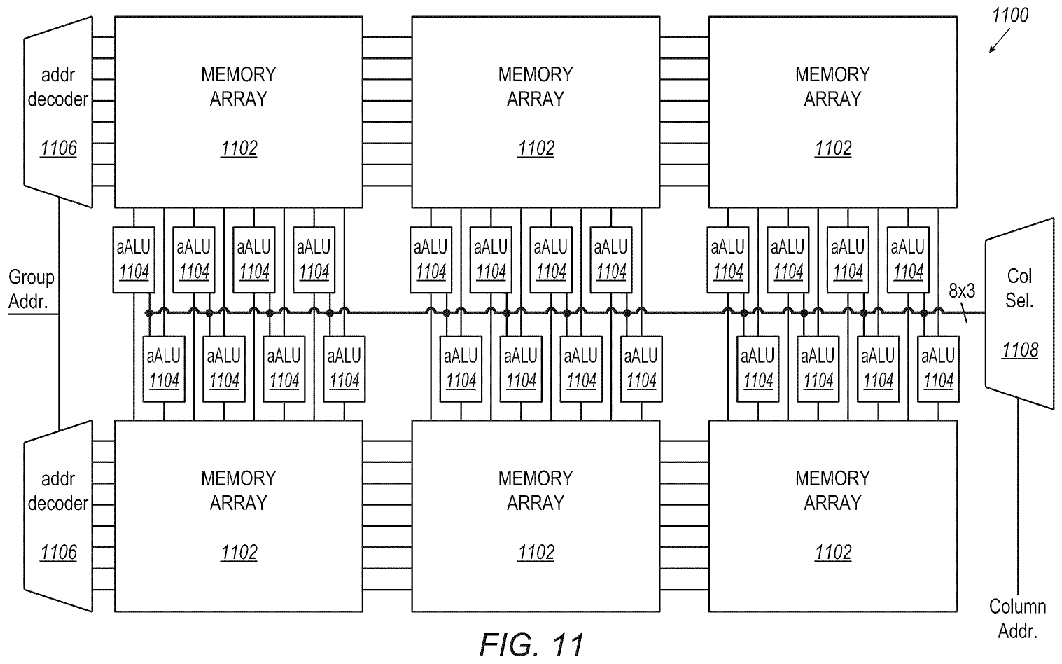

FIG. 11 is a block diagram that schematically illustrates a six-bank a DRAM device 1100 comprising an analog refresh loop, in accordance with an embodiment of the present invention. DRAM Device 1100 comprises six Memory Arrays (“Banks”). The Memory Arrays store analog values that represent Nibbles in the digital domain. Each Memory Array 1102 is configured to handle eight Nibbles concurrently (in other words, the Memory Array is, in the digital domain, 8-nibble wide).

DRAM Device 1100 further comprises 24 aALUs 1104; each aALU is shared by a Memory Array 1102 of the top row of Memory Arrays, and a Memory Array of the bottom row. Thus, DRAM Device 1100 has, in the digital domain, a width of 24 Nibbles.

A pair of Address Decoders 1106 select respective groups in the top and in the bottom rows of Memory Arrays 1102, according to the Group-Address input (in an embodiment, the Group-Address input comprises four bits; the most-significant bit selects between the top and the bottom Address Decoders 1106, whereas the least-significant three bits are input to both Address Decoders).

Lastly, a Column-Selector 1108 selects, according to a Column Address input, the outputs of three aALUs 1104 (one aALU from each pair of Memory Arrays 1102).

The configuration of six-bank a DRAM device 1100, illustrated in FIG. 11 and described herein above is cited by way of example. Other configurations may be used in alternative embodiments. For example, in some embodiments, the number of banks may be different from six; in other embodiments the number of address lines may be higher or lower than four and in yet other embodiments the number of Nibbles per Memory Array may be different from eight. In an embodiment, each aALU 1104 is shared by more than two Memory Arrays, and in another embodiment the aALUs are not shared.

The apparatuses, waveforms and methods described hereinabove, with reference to FIGS. 1 through 11; the configurations DRAM device 200, 1000, 1100; the configuration of aALU 300 and aALU 400, the configuration of Voltage-Ratio Amplifier 700, Log Amplifier 800 and Anti-Log Amplifier 850, the Write waveforms 500 and the Refresh Waveforms 600, and the method of flowchart 900, including all units and subunits thereof, are example configurations, waveforms and methods that are shown purely for the sake of conceptual clarity. Any other suitable methods, waveforms and configurations can be used in alternative embodiments.

The continuous analog memory device described herein above comprises a physical layer for an efficient data intensive storage structure, exploiting an additional link layer for pre-coding, calibration and other functions, in the implementation of an adaptive software defined memory solution.

It should be noted that, while the term DRAM Device may imply, besides the memory array, additional circuitry such as decoders, I/O buffers and others, the term DRAM device used hereinabove applies to both a complete DRAM device and to parts thereof, such as the memory array.

In various embodiments, DRAM Device 100, including subunits thereof, may be implemented using suitable hardware, such as one or more Application-Specific Integrated Circuits (ASIC) or Field-Programmable Gate Arrays (FPGA), or a combination of ASIC and FPGA.

Although the embodiments described herein mainly address analog DRAM, the methods and systems described herein can also be used in other applications such as in various ultra-low-power analog-only circuits and in ICs that combine analog-ALU and analog memory.

It will thus be appreciated that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. A Dynamic Random-Access Memory (DRAM) device, comprising:
a plurality of DRAM cells comprising respective storage capacitors configured to be charged to respective voltages;
a control circuit, configured to read a voltage from a target DRAM cell and to refresh the target DRAM cell using a refresh voltage that is derived from the read voltage; and
an analog Arithmetic-Logic Unit (aALU), configured to derive the refresh voltage from the read voltage such that the refresh voltage approximates a voltage previously written to the target DRAM cell, by performing analog operations.

2. The DRAM device according to claim 1, wherein one or more of the DRAM cells serve as one or more reference DRAM cells that are programmed with one or more respective reference voltages, and wherein the aALU is configured to derive the refresh voltage for the target DRAM cell based on (i) the voltage read from the target DRAM cell, (ii) one or more voltages read from the one or more reference DRAM cells, and (iii) a time that elapsed since the voltage was previously written to the target DRAM cell.

3. The DRAM device according to claim 1, wherein the aALU comprises (i) one or more reference sampling capacitors configured to store one or more sampled reference DRAM cell voltages and (ii) a data sampling capacitor configured to store a sampled target DRAM data voltage.

4. The DRAM device according to claim 1, wherein the aALU comprises a voltage-ratio amplifier that is configured to produce the refresh voltage by multiplying a reference voltage among the one or more reference voltages by a ratio between the corrected target DRAM cell voltage and a respective corrected reference DRAM cell voltage among the one or more corrected reference DRAM cell voltages, thereby mitigating a decay of the target DRAM cell.

5. The DRAM device according to claim 4, wherein the aALU comprises a differential amplifier, which is configured to:
amplify a difference between the precharge voltage and the data-read voltage by a reciprocal of a charge sharing attenuation factor, thereby producing a corrected target DRAM cell voltage for the target DRAM cell; and
amplify one or more differences between the precharge voltage and the one or more reference-read voltages by a reciprocal of a charge sharing attenuation factor, thereby producing one or more corrected reference DRAM cell voltages for the one or more reference DRAM cells.

6. The DRAM device according to claim 4, wherein the aALU is configured to produce the refresh voltage by adding a product of (i) a DRAM cell decay measure and (ii) a difference between a corrected first reference voltage among the one or more corrected reference voltages and a respective first reference voltage among the one or more reference voltages, to a first reference voltage among the one or more reference voltages, thereby compensating for additive noise that is induced on the storage capacitors.

7. The DRAM device according to claim 6, wherein the aALU is configured to calculate the DRAM cell decay measure by dividing a difference between a first reference voltage and a second reference voltage by a difference between a first corrected reference voltage and a second corrected reference voltage.

8. The DRAM device according to claim 1, wherein the aALU comprises a differential amplifier, which is configured to amplify a difference between a precharge voltage and a voltage read from the target DRAM cell, and wherein the aALU is configured to produce a corrected target DRAM cell voltage for the target DRAM cell based on an analog output of the differential amplifier.

9. The DRAM device according to claim 1, wherein, in deriving the refresh voltage from the read voltage, the aALU is configured to compensate for one or more of (i) a process variation affecting the DRAM device, (ii) a variation associated with a supply voltage of the DRAM device, and (iii) a variation associated with a temperature of the DRAM device.

10. An analog Dynamic Random-Access Memory (analog-DRAM) device, comprising a plurality of storage capacitors that are configured to store a continuous range of an electric charge, representing a continuously defined analog value.

11. A method, comprising:
operating a plurality of Dynamic Random-Access Memory (DRAM) cells comprising respective storage capacitors configured to be charged to respective voltages;
using a control circuit, reading a voltage from a target DRAM cell and refreshing the target DRAM cell using a refresh voltage that is derived from the read voltage; and
using an analog Arithmetic-Logic Unit (aALU), deriving the refresh voltage from the read voltage such that the refresh voltage approximates a voltage previously written to the target DRAM cell, by performing analog operations.

12. The method according to claim 11, wherein one or more of the DRAM cells serve as one or more reference DRAM cells that are programmed with one or more respective reference voltages, and wherein deriving the refresh voltage for the target DRAM cell is based on (i) the voltage read from the target DRAM cell, (ii) one or more voltages read from the one or more reference DRAM cells, and (iii) a time that elapsed since the voltage was previously written to the target DRAM cell.

13. The method according to claim 11, wherein deriving the refresh voltage comprises (i) storing one or more sampled reference DRAM cell voltages in one or more reference sampling capacitors of the aALU, and (ii) storing a sampled target DRAM data voltage in a data sampling capacitor of the aALU.

14. The method according to claim 11, wherein deriving the refresh voltage comprises producing the refresh voltage using a voltage-ratio amplifier in the aALU, by multiplying a reference voltage among the one or more reference voltages by a ratio between the corrected target DRAM cell voltage and a respective corrected reference DRAM cell voltage among the one or more corrected reference DRAM cell voltages, thereby mitigating a decay of the target DRAM cell.

15. The method according to claim 14, wherein deriving the refresh voltage comprises, using a differential amplifier in the aALU:
amplifying a difference between the precharge voltage and the data-read voltage by a reciprocal of a charge sharing attenuation factor, thereby producing a corrected target DRAM cell voltage for the target DRAM cell; and
amplifying one or more differences between the precharge voltage and the one or more reference-read voltages by a reciprocal of a charge sharing attenuation factor, thereby producing one or more corrected reference DRAM cell voltages for the one or more reference DRAM cells.

16. The method according to claim 14, wherein deriving the refresh voltage comprises producing the refresh voltage by adding a product of (i) a DRAM cell decay measure and (ii) a difference between a corrected first reference voltage among the one or more corrected reference voltages and a respective first reference voltage among the one or more reference voltages, to a first reference voltage among the one or more reference voltages, thereby compensating for additive noise that is induced on the storage capacitors.

17. The method according to claim 16, wherein deriving the refresh voltage comprises calculating the DRAM cell decay measure by dividing a difference between a first reference voltage and a second reference voltage by a difference between a first corrected reference voltage and a second corrected reference voltage.

18. The method according to claim 11, wherein deriving the refresh voltage comprises amplifying a difference between a precharge voltage and a voltage read from the target DRAM cell using a differential amplifier in the aALU, and producing a corrected target DRAM cell voltage for the target DRAM cell based on an analog output of the differential amplifier.

19. The method according to claim 11, wherein deriving the refresh voltage comprises compensating for one or more of (i) a process variation affecting the DRAM cells, (ii) a variation associated with a supply voltage of the DRAM cells, and (iii) a variation associated with a temperature of the DRAM cells.
